(19) United States
(12) Patent Application Publication
(10) Pub. No.: US 2026/0269603 A1
(43) Pub. Date: Sep. 10, 2026

(54) AC POWER GENERATION COMPRISING A NON-INDUCTIVE OVERVOLTAGE PROTECTION DEVICE

(71) Applicant: SAFRAN ELECTRICAL & POWER SAS, BLAGNAC (FR)

(72) Inventor: Francis ABDESSELAM, MOISSY-CRAMAYEL (FR)

(21) Appl. No.: 19/139,134

(22) PCT Filed: Dec. 19, 2023
(86) PCT No.: PCT/EP2023/086660

§ 371 Date: Jun. 13, 2025

(30) Foreign Application Priority Data
Dec. 19, 2022 (FR) FR2213765

(51) Int. Cl. H02H 9/04; G01R 31/42; H02H 1/00

(52) U.S. Cl. CPC H02H 9/045; G01R 31/42; H02H 1/0007; H02H 9/043

(57) ABSTRACT

A device for protecting against fast overvoltages and slow overvoltages placed in parallel with an alternating-current generation line includes: a first current source including an input and an output, the input of the first current source being connected to a first terminal of the generation line, a second current source including an input and an output, the input of the second current source being connected to a second terminal of the generation line, the output of the second current source being connected to the output of the first current source.

### CROSS-REFERENCE TO RELATED APPLICATIONS

This application is a National Stage of International patent application PCT/EP2023/086660, filed on Dec. 19, 2023, which claims priority to foreign French patent application No. FR 2213765, filed on Dec. 19, 2022, the disclosures of which are incorporated by reference in their entireties.

### FIELD OF THE INVENTION

The invention relates to protection of loads connected to an AC electrical generation line. More precisely, the invention is related to protecting against overvoltages in an AC electrical network. The invention is of particular interest in the field of aeronautics, in which the safety of AC electrical circuits and networks is of paramount importance, but it is also of interest in the field of electricity generation in a network requiring, for example, an inductive machine to be used.

### BACKGROUND

In an AC electrical network, various types of transient or more durable overvoltages may be detected. Furthermore, these overvoltages may damage electrical or electronic equipment and lead to catastrophic events in particular when it is a question of systems associated with a high availability and a low failure rate.

Currently, overvoltages may be divided into two types:
“fast” overvoltages for which the reaction time, i.e. the time taken to compensate for the overvoltage, must be short to prevent major disruption to the electrical network,
“slow” overvoltages that lead to greater generation of power but for which a short reaction time is not required to manage the overvoltage in the network.

Usually, protection against fast overvoltages and slow overvoltages is ensured by different protecting systems.

Thus, in order to protect the AC electrical network against a fast overvoltage, a user may decide to incorporate into the circuit:
a Transil Zener diode or active clipper, which has a very short reaction time (less than one nanosecond) but absorbs only a small amount of energy. Furthermore, this type of component has an overvoltage tolerance of less than 5%, i.e. the overvoltage must not be very high compared to the voltage usually measured in the network, and generates high-frequency distortion when used;
a zinc-oxide varistor, which has a short reaction time (between about ten nanoseconds and about one hundred nanoseconds) but is likewise able to absorb only a small amount of energy. In addition, this type of component has a low overvoltage tolerance though one that is still higher than a Zener diode's. Nevertheless, unlike a Zener diode, a ZNO varistor has the advantage of not generating distortion in the network;
a spark gap, which for its part has a relatively longer reaction time than the abovementioned components (from a few microseconds to one millisecond) but which has the advantage of absorbing a large amount of energy during an overvoltage. Furthermore, its overvoltage tolerance is also large with respect to the abovementioned components. Nevertheless, this component has the drawback of causing network unavailability;
and, lastly, a crowbar resistor may also be envisioned. This component has a reaction time and energy absorption capacity equivalent to those of the spark gap. Nonetheless, this component has an overvoltage tolerance equivalent to that of a ZNO varistor and renders the electrical network unavailable during its use.

Nevertheless, none of these components is able to protect the network when a slow overvoltage, generating a substantial amount of power in the network, occurs.

Thus, in order to protect the circuit against a slow overvoltage, it is known in the art to add to the circuit a switched resistor allowing the power generated to be absorbed. However, this component also generates an overvoltage on opening.

Thus, there is currently no component allowing a fast overvoltage and a slow overvoltage to be handled, and those skilled in the art are obliged to add a plurality of components to their networks, this sometimes being unfeasible when the available space is small.

The invention aims to overcome all or some of the abovementioned problems by providing a device for protecting against fast overvoltages and slow overvoltages that does not generate distortion and does not decrease the power available on the electrical network.

Furthermore, this protecting device is advantageously characterized by a short reaction time (less than one microsecond) and its ability to independently clip positive and negative overvoltages.

### SUMMARY OF THE INVENTION

To this end, the subject of the invention is an electrical power generator configured to deliver electrical power to a load through an alternating-current generation line, the electrical power generator comprising a device for protecting against fast overvoltages and slow overvoltages, placed in parallel with the alternating-current generation line, the protecting device comprising:
a first current source comprising an input and an output, the input of the first current source being connected to a first terminal of the generation line,
a second current source comprising an input and an output, the input of the second current source being connected to a second terminal of the generation line, the output of the second current source being connected to the output of the first current source.

According to one aspect of the invention, the first current source and/or second current source are/is configured to generate a current proportional to a voltage measurable at the first current source or second current source.

According to one aspect of the invention, the device for protecting against overvoltages comprises an overvoltage detector configured to detect an overvoltage level between the first terminal and second terminal of the generation line, the overvoltage level being a voltage across the first terminal and second terminal of the generation line greater than a first predefined threshold voltage. According to one aspect of the invention, the first current source comprises:
a first transistor, the first transistor comprising:
   a first terminal connected to the first terminal of the generation line,
   a second terminal connected to the first terminal of the generation line,
   a third terminal connected to the second current source,
a first diode comprising a cathode connected to the first terminal of the first transistor and an anode connected to the third terminal of the first transistor,
a first resistor placed between the first terminal of the generation line and the second terminal of the first transistor and connected to the overvoltage detector,
a first current regulator connected to the overvoltage detector, placed between the first resistor and the second terminal of the first transistor and configured to limit the current flowing through the first transistor to a predefined current.

According to one aspect of the invention, the first current source comprises a first device for activating the first regulator, which device is connected to the overvoltage detector and configured to switch from a deactivated state, in which the first regulator is inactive, to an activated state, in which the first regulator is active, when the overvoltage detector detects the overvoltage level, the first activating device comprising:
a first auxiliary voltage detector configured to determine a voltage across the first terminal and second terminal of the generation line,
a first current detector, which is placed between the third terminal of the first transistor and the second current source and configured to determine a current at the third terminal of the first transistor,
the first activating device being configured to switch from the activated state to the deactivated state when the voltage determined by the first auxiliary voltage detector is less than a second predefined voltage and when the current determined by the first current detector is zero.

According to one aspect of the invention, the second current source comprises: a second transistor, the second transistor comprising:
a first terminal connected to the second terminal of the generation line, a second terminal connected to the second terminal of the generation line,
a third terminal connected to the first current source,
a second diode comprising a cathode connected to the first terminal of the second transistor and an anode connected to the third terminal of the second transistor,
a second resistor placed between the second terminal of the generation line and the second terminal of the second transistor and connected to the overvoltage detector,
a second current regulator connected to the overvoltage detector, placed between the second resistor and the second terminal of the second transistor and configured to limit the current flowing through the second transistor to a predefined current.

According to one aspect of the invention, the second current source comprises a second device for activating the second regulator, which device is connected to the overvoltage detector and configured to switch from a deactivated state, in which the second regulator is inactive, to an activated state, in which the second regulator is active, when the overvoltage detector detects the overvoltage level, the second activating device comprising:
a second auxiliary voltage detector configured to determine a voltage across the first terminal and second terminal of the generation line,
a second current detector, which is placed between the third terminal of the second transistor and the first current source and configured to determine a current at the third terminal of the second transistor,
the second activating device being configured to switch from the activated state to the deactivated state when the voltage determined by the second auxiliary voltage detector is less than a third predefined voltage and when the current determined by the second current detector is zero.

According to one aspect of the invention, the first transistor is a bipolar transistor.

According to one aspect of the invention, the second transistor is a bipolar transistor.

According to one aspect of the invention, the protecting device comprises a device for opening the protecting device.

According to one aspect of the invention, the protecting device comprises a first protecting unit, the first protecting unit comprising the first current source and the second current source, the protecting device comprising at least one additional protecting unit comprising a first additional current source identical to the first current source and a second additional current source identical to the second current source, the at least one additional protecting unit shunting the first protecting unit.

### BRIEF DESCRIPTION OF THE DRAWINGS

The invention will be better understood and other advantages will become apparent on reading the detailed description of one embodiment that is given by way of example, the description being illustrated by the appended drawing in which:

FIG. 1 shows a schematic view of a device for protecting against fast overvoltages and slow overvoltages according to the invention;

FIG. 2 shows an enlarged view of the protecting device of FIG. 1;

FIG. 3 shows a structural view of the protecting device of FIG. 1;

FIG. 4 shows the protecting device according to a first variant;

FIG. 5 shows the protecting device according to a second variant;

FIG. 6 shows a timing diagram of the impact of the protecting device on the electrical machine according to the invention;

FIG. 7A shows a timing diagram of the wave behavior in an electrical generation line in the absence of the protecting device according to the invention;

FIG. 7B shows a timing diagram of the wave behavior in an electrical generation line in the presence of the protecting device according to the invention.

For the sake of clarity, elements that are the same have been designated by the same reference signs in the various figures.

### DETAILED DESCRIPTION

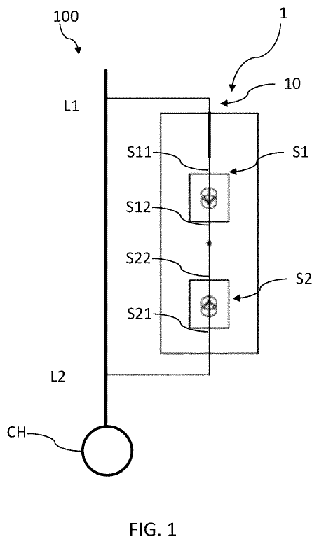

FIG. 1 thus shows a schematic view of an electrical power generator 100 configured to deliver electrical power to a load CH via an electrical-current generation line L1-L2. The load CH is thus connected in parallel with the electrical-current generation line L1-L2. The power generator comprises a device 1 for protecting against fast overvoltages and slow overvoltages placed in parallel with an alternating-current generation line L1-L2, between a first terminal L1 and a second terminal L2. The protecting device is placed in parallel with the load CH. As stated above, the current between the first terminal L1 and second terminal L2 in the generation line L1-L2 is an alternating current, this meaning that the direction of the electrical current may be from the first terminal L1 to the second terminal L2 or from the second terminal L2 to the first terminal L1. The protecting device 1 is therefore placed on its own line 10 parallel to the generation line L1-L2.

The protecting device 1 comprises a first current source S1 comprising an input S11 and an output S12. Furthermore, the input S11 of the first current source S1 is connected to the first terminal L1 of the generation line L1-L2.

The protecting device 1 also comprises a second current source S2, which also comprises an input S21 and an output S22. Furthermore, the input S21 of the second current source S2 is connected to the second terminal L2 of the generation line L1-L2, while the output S22 of the second current source S2 is connected to the output S12 of the first current source S1.

The first current source S1 is thus directly connected to the second current source S2 via the connection between the output S12 of the first current source S1 and the output S22 of the second current source S2.

This arrangement thus has the advantage of making it possible to regulate any overvoltage irrespectively of whether, depending on the direction of the current, it is positive or negative.

In other words, the first current source S1 and the second current source S2 are positioned in series on the line 10. The second current source S2 is positioned so as to oppose the first current source S1. The second current source S2 is thus positioned “back-to-back” with respect to the first current source S1.

Thus, when the direction of the current is from the first terminal L1 to the second terminal L2, then the first current source S1 is active because it is in the direction of the current while the second current source S2 is, for its part, opposed to the direction of the current and therefore inactive. Conversely, when the direction of the current is from the second terminal L2 to the first terminal L1, then the second current source S2 is active because it is in the direction of the current while the first current source S1 is, for its part, opposed to the direction of the current and therefore inactive.

As a variant, the first current source S1 and/or the second current source S2 may be a controlled active means for generating current.

By first current source S1 and by second current source S2, what is to be understood is that the first current source S1 and second current source S2 are devices capable of producing an electrical current that operate in a voltage range.

More precisely, the voltage measurable in the generation line L1-L2 is identical to the voltage measurable in the line 10. If an overvoltage is detected between the first terminal L1 and second terminal L2, this overvoltage is also detected in the protecting device 1. Now, since the current is proportional to the voltage across the terminals of the generation line L1-L2 and in the line 10, the protecting device 1 makes it possible, by adapting the current, to regulate the voltage in the protecting device 1 and in the generation line L1-L2.

In other words, when the direction of the electrical current is from the first terminal L1 to the second terminal L2 and when an overvoltage is detected in the generation line L1-L2, then the first current source S1 makes it possible to generate an electrical current in the line 10 so as to regulate the voltage on the same line 10 and therefore also in the generation line L1-L2, so as to limit the overvoltage. Furthermore, when the direction of the electrical current is from the second terminal L2 to the first terminal L1 and when an overvoltage is detected in the generation line L1-L2, then the second current source S2 makes it possible to generate an electrical current in the line 10 so as to regulate the voltage on the same line 10 and therefore also in the generation line L1-L2, so as to limit the overvoltage. The protecting device 1 therefore makes it possible to limit the voltage in the circuit, namely the generation line L1-L2 and the line 10, by regulating the current flowing through the protecting device 1 in a very short time, less than one nanosecond.

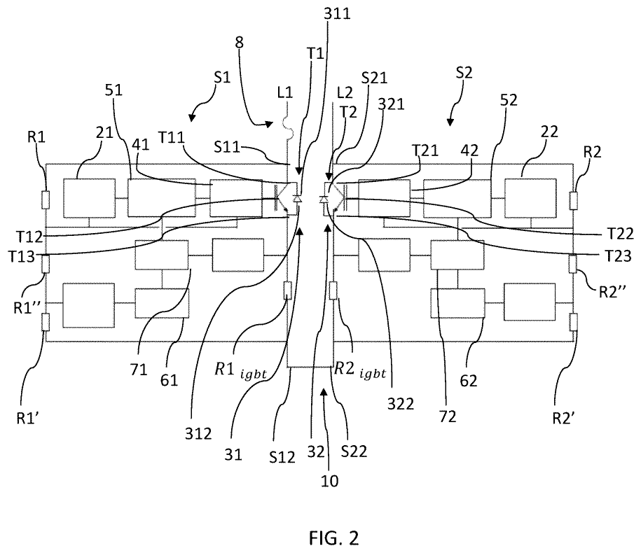

FIG. 2 shows an enlarged view of the protecting device 1.

The first current source S1 comprises a first transistor T1 connected to the first terminal L1. The first transistor T1 comprises:
a first terminal T11 connected to the first terminal L1 of the generation line L1-L2,
a second terminal T12 also connected to the first terminal L1 of the generation line L1-L2,
and a third terminal T13 connected to the second current source S2.

The first transistor T1 is a power IGBT. It may also be envisioned for the first transistor T1 to be a bipolar transistor. Thus, the first terminal T11 of the bipolar transistor is then a collector, the second terminal T12 of the bipolar transistor is then a base and the third terminal T13 of the bipolar transistor is an emitter.

It may also be envisioned for the first transistor T1 to be a MOS transistor. Thus, the first terminal T11 of the MOS transistor is then a drain, the second terminal T12 of the MOS transistor is then a gate and the third terminal T13 of the MOS transistor is a source.

The first current source S1 also comprises a first diode 31 placed between the first terminal T11 of the first transistor T1 and the third terminal T13 of the first transistor T1. In other words, the first diode 31 comprises a cathode 311 connected to the first terminal T11 of the first transistor T1 and an anode 312 connected to the third terminal T13 of the first transistor T1.

Thus, as stated above, when the direction of the current is from the first terminal L1 to the second terminal L2, the current coming from the first terminal L1 flows only through the power transistor T1, which is on since the first diode 31, and more precisely the cathode 311, is reverse biased.

Thus, in order to be able to detect potential overvoltage in the generation line L1-L2 and in the line 10, the protecting device 1 comprises a first overvoltage detector 21 configured to detect an overvoltage level OvH between the first terminal L1 and second terminal L2 of the generation line L1-L2. The overvoltage level OvH is a voltage across the first terminal L1 and second terminal L2 of the generation line L1-L2 greater than a first predefined threshold voltage V_{high}. By way of indicative example, the first threshold voltage V_{high} may be 200 volts for generation of 115 Vac.

The first overvoltage detector 21 is placed so as to measure the voltage across the first terminal L1 and the second terminal T12 of the first transistor T1. It may also be envisioned for the first overvoltage detector 21 to be placed so as to measure the voltage across the first terminal L1 and the first terminal T11 of the first transistor T1.

Furthermore, the first current source S1 comprises a first resistor R1 so as to make it possible to determine the electrical potential between the first terminal L1 and second terminal L2 in the electrical generation line L1-L2. It may be envisioned, in one preferred configuration, for the first overvoltage detector 21 to be connected to the first resistor R1 in order to facilitate measurement of the voltage in the line 10.

The first current source S1 also comprises a first current regulator 41 connected to the first overvoltage detector 21 and configured to regulate the current flowing through the first transistor T1 to a current proportional to the voltage present across the first terminal L1 and second terminal L2, having a maximum value of 20 amps for example.

In addition, the first current source S1 comprises a first device 51 for activating the first regulator 41, which device is connected to the first overvoltage detector 21 and configured to switch from a deactivated state, in which the first regulator 41 is inactive, to an activated state, in which the first regulator 41 is active, when the first overvoltage detector 21 detects the overvoltage level OvH. In other words, the first device 51 for activating the first regulator 41 is a state device configured to switch between two states: an activated state and a deactivated state.

When the first device 51 for activating the first regulator 41 is in the activated state, then the first activating device 51 allows the first regulator 41 to regulate the current flowing through the first current source S1 and the line 10 from the first terminal L1 to the second terminal L2. Furthermore, when the first device 51 for activating the first regulator 41 is in the deactivated state, then the first activating device 51 switches off regulation by the first regulator 41 of the current in the line 10 from the first terminal L1 to the second terminal L2, and hence the first current source S1, and more particularly the first regulator 41, does not apply regulation to the line 10. Thus, the first device 51 for activating the first regulator 41 switches to an activated state when the first overvoltage detector 21 detects the overvoltage level OvH and to the deactivated state when no overvoltage is detected by the first overvoltage detector 21.

The first activating device 51 comprises a first auxiliary voltage detector 61 configured to determine a voltage across the first terminal L1 and second terminal L2 of the generation line L1-L2. More precisely, the first auxiliary voltage detector 61 may be configured to measure the voltage across the second terminal T12 of the first transistor T1 and the second terminal L2. To do this, a first auxiliary resistor R1′ may be positioned between the second terminal T12 of the first transistor T1 and the second terminal L2, so as to allow the first auxiliary voltage detector 61 to measure the voltage across the terminals of the first auxiliary resistor R1′. In other words, the first auxiliary resistor R1′ makes it possible to provide an image of the voltage across the second terminal T12 of the first transistor T1 and the second terminal L2. The first auxiliary voltage detector 61 thus makes it possible to generate a first condition C1 of switching of the first device 51 for activating the first regulator 41 between the activated state and the deactivated state. This first switching condition C1 is measurement, by the first auxiliary voltage detector 61, of a voltage that, in absolute value, is less than a second predefined threshold voltage Vₙₒₘ. By way of indicative example, the second threshold voltage Vₙₒₘ may be 170 volts for generation of 115 Vac.

The first current source S1 may also comprise a first regulating resistor R1″ configured to measure the electrical potential between the first terminal L1 and a terminal C located between the first current source S1 and the second current source S2. This first regulating resistor makes it possible to achieve a proportionality between the voltage measurable across the first terminal L1 and the terminal C and the current flowing through the first current source S1.

The first activating device 51 also comprises a first current detector 71, which is placed between the third terminal T13 of the first transistor T1 and the second current source S2 and configured to determine a current at the third terminal T13 of the first transistor T1. The first current detector 71 thus makes it possible to obtain a reliable measurement of the current at the output of the first transistor T1. The first current detector 71 thus makes it possible to generate a second condition C2 of switching of the first device 51 for activating the first regulator 41 between the activated state and the deactivated state. This second switching condition C2 is measurement, by the first current detector 71, of zero current at the output of the first transistor T1. It may be envisioned for the first current detector 71 to be connected to a first transistor resistor R1_{igbt} connected to the third terminal T13 of the first transistor T1. The first transistor resistor R1_{igbt} is a resistor of low resistance allowing an image of the current flowing through the first current source S1 to be obtained.

Thus, the first activating device 51 is configured to switch from the activated state to the deactivated state when the voltage determined by the first auxiliary voltage detector 61 is less than the second predefined voltage Vₙₒₘ and when the current determined by the first current detector 71 is zero. In other words, the first activating device 51 is able to switch from the activated state to the deactivated state only when the first condition C1 and the second condition C2 are both met. Therefore, when the first condition C1 and second condition C2 are met, there is no overvoltage, the electrical generation line L1-L2 and the line 10 are in a nominal operating state, and the first regulator 41 is inactive.

In contrast, the only condition that must be met for the first device 51 for activating the first regulator 41 to switch from the deactivated state to the activated state is detection by the first overvoltage detector 21 of a voltage greater than the first threshold voltage V_{high} and therefore of an overvoltage level OvH. Therefore, an overvoltage is present, the electrical generation line L1-L2 and the line 10 are in a malfunctioning state, and the first regulator 41 is active.

Specifically, the presence of a voltage measurement less than the second threshold voltage Vₙₒₘ is thus indicative of the fact that the voltage across the first terminal L1 and second terminal L2 is insufficient to degrade the components between the first terminal L1 and second terminal L2. Furthermore, the presence of a zero current at the output of the first transistor T1 is thus indicative of an inversion of the direction of the current between the first terminal L1 and second terminal L2.

Moreover, similarly, the second current source S2 comprises a second transistor T2 connected to the second terminal L2. The second transistor T2 comprises:
a first terminal T21 connected to the second terminal L2 of the generation line L1-L2,
a second terminal T22 also connected to the second terminal L2 of the generation line L1-L2,
and a third terminal T23 connected to the first current source S1.

The second transistor T2 is a power transistor. It may also be envisioned for the second transistor T2 to be a bipolar transistor. Thus, the first terminal T21 of the bipolar transistor is then a collector, the second terminal T22 of the bipolar transistor is then a base and the third terminal T23 of the bipolar transistor is an emitter.

It may also be envisioned for the second transistor T2 to be a MOS transistor. Thus, the first terminal T21 of the MOS transistor is then a drain, the second terminal T22 of the MOS transistor is then a gate and the third terminal T23 of the MOS transistor is a source.

The second current source S2 also comprises a second diode 32 placed between the first terminal T21 of the second transistor T2 and the third terminal T23 of the second transistor T2. In other words, the second diode 32 comprises a cathode 321 connected to the first terminal T21 of the second transistor T2 and an anode 322 connected to the third terminal T23 of the second transistor T2.

Thus, when the direction of the current is from the second terminal L2 to the first terminal L1, the current coming from the second terminal L2 flows only through the second transistor T2, which is on since the second diode 32 is reverse biased. More precisely, when the current is directed from the first terminal L1 to the second terminal L2, then the current flows through the first transistor T1, which is on, while the first diode 31 is reverse biased, then the second diode 32, which is forward biased, while the second transistor T2 is off, before reaching the second terminal L2. In contrast, when the current is directed from the second terminal L2 to the first terminal L1, then the current flows through the second transistor T2, which is on, while the second diode 32 is reverse biased, then the first diode 31 which is forward biased, while the first transistor T1 is off, before reaching the first terminal L1.

Thus, in order to be able to detect potential overvoltage in the generation line L1-L2 and in the line 10 when the current is directed from the second terminal L2 to the first terminal L1, the protecting device 1 comprises a second overvoltage detector 22 configured to detect a second overvoltage level OvH′ between the second terminal L2 and first terminal L1 of the generation line L1-L2. The second overvoltage level OvH′ is a voltage across the second terminal L2 and first terminal L1 of the generation line L1-L2 greater than a third predefined threshold voltage V′_{high}. By way of indicative example, the third threshold voltage V′_{high} may be −200 volts for generation of 115 Vac Specifically, since the voltage is measured from the second terminal L2 to the first terminal L1, the voltage is negative with respect to the electrical generation line L1-L2.

In a preferred configuration, the first overvoltage detector 21 and second overvoltage detector 22 are included in a single overvoltage detector comprising various sensors for measuring voltage at the first transistor T1 and second transistor T2. This configuration has the advantage of making it possible to limit the bulk of the protecting device 1.

Furthermore, it may also be envisioned for the absolute value of the third threshold voltage V′_{high} to be identical to the absolute value of the first threshold voltage V_{high} so that the single overvoltage detector is configured to measure the absolute value of the voltage in the electrical generation line L1-L2, irrespectively of the direction of the current. Therefore, the absolute value of the overvoltage level OvH is identical to the absolute value of the second overvoltage level OvH′ and hence the voltage is deemed acceptable when the voltage measured by the single overvoltage detector or by the first overvoltage detector 21 or by the second overvoltage detector 22 is between the first threshold voltage V_{high} and the third threshold voltage V′_{high}.

The second overvoltage detector 22 is placed so as to measure the voltage across the second terminal L2 and the second terminal T22 of the second transistor T2. It may also be envisioned for the second overvoltage detector 22 to be placed so as to measure the voltage across the second terminal L2 and the first terminal T21 of the second transistor T2.

Furthermore, the second current source S2 comprises a second resistor R2 so as to make it possible to determine the electrical potential between the first terminal L1 and second terminal L2 in the electrical generation line L1-L2. It may be envisioned, in one preferred configuration, for the second overvoltage detector 22 to be connected to the second resistor R2 in order to facilitate measurement of the voltage in the line 10.

It may also be envisioned, as mentioned above, for the single overvoltage detector to be connected to the first resistor R1 and to the second resistor R2.

The second current source S2 also comprises a second current regulator 42 connected to the second overvoltage detector 22 and configured to limit the current flowing through the second transistor T2 to a predefined current having a maximum value of 20 amps for example. In one preferred configuration, the second regulator 42 is placed between the second resistor R2 and the second terminal T22 of the second transistor T2. Nevertheless, any other arrangement may be envisioned provided that the second current regulator 42 is connected to the second overvoltage detector 22.

As a variant, the first regulator 41 and the second regulator 42 may be included in a single regulator making it possible to limit the bulk of the protecting device 1.

In addition, the second current source S2 comprises a second device 52 for activating the second regulator 42, which device is connected to the second overvoltage detector 22 and configured to switch from a deactivated state, in which the second regulator 42 is inactive, to an activated state, in which the second regulator 42 is active, when the second overvoltage detector 22 detects the second overvoltage level OvH′. In other words, the second device 52 for activating the second regulator 42 is a state device configured to switch between two states: an activated state and a deactivated state.

When the second device 52 for activating the second regulator 42 is in the activated state, then the second activating device 52 allows the second regulator 42 to regulate the current flowing through the second current source S2 and the line 10 from the second terminal L2 to the first terminal L1. Furthermore, when the second device 52 for activating the second regulator 42 is in the deactivated state, then the second activating device 52 switches off regulation by the second regulator 42 of the current in the line 10 from the second terminal L2 to the first terminal L1, and hence the second current source S2, and more particularly the second regulator 42, does not apply regulation to the line 10. Thus, the second device 52 for activating the second regulator 42 switches to an activated state when the second overvoltage detector 22 detects the second overvoltage level OvH′ and to the deactivated state when no overvoltage is detected by the second overvoltage detector 22.

The second activating device 52 comprises a second auxiliary voltage detector 62 configured to determine a voltage across the second terminal L2 and first terminal L1 of the generation line L1-L2. More precisely, the second auxiliary voltage detector 62 may be configured to measure the voltage across the second terminal T22 of the second transistor T2 and the first terminal L1. To do this, a second auxiliary resistor R2′ may be positioned between the second terminal T22 of the second transistor T2 and the first terminal L1, so as to allow the second auxiliary voltage detector 62 to measure the voltage across the terminals of the second auxiliary resistor R2′. In other words, the second auxiliary resistor R2′ makes it possible to provide an image of the voltage across the second terminal T22 of the second transistor T2 and the first terminal L1. The second auxiliary voltage detector 62 thus also makes it possible to generate the first condition C1 of switching of the second device 52 for activating the second regulator 42 between the activated state and the deactivated state. Furthermore, similarly, the first switching condition C1 is measurement, by the second auxiliary voltage detector 62, of a voltage that, in absolute value, is less than the second predefined threshold voltage Vₙₒₘ.

The second current source S2 may also comprise a second regulating resistor R2″ configured to measure the electrical potential between the second terminal L2 and the terminal C located between the first current source S1 and the second current source S2. This second regulating resistor R2″ thus makes it possible to achieve a proportionality between the voltage measurable across the second terminal L2 and the terminal C and the current flowing through the second current source S1.

The second activating device 52 also comprises a second current detector 72, which is placed between the third terminal T23 of the second transistor T2 and the first current source S1 and configured to determine a current at the third terminal T23 of the second transistor T2. The second current detector 72 thus makes it possible to obtain a reliable measurement of the current at the output of the second transistor T2. It may be envisioned for the second current detector 72 to be connected to a second transistor resistor R2_{igbt} connected to the third terminal T23 of the second transistor T2. The second transistor resistor R2_{igbt} is a resistor of low resistance allowing an image of the current flowing through the second current source S2 to be obtained. The second current detector 72 thus makes it possible to generate the second condition C2 of switching of the second device 52 for activating the second regulator 42 between the activated state and the deactivated state. Similarly, the second switching condition C2 is measurement, by the second current detector 72, of zero current at the output of the second transistor T2. Therefore, the second condition C2 is met when a current of zero is measured between the first transistor T1 and second transistor T2, indicating an inversion of the direction of the current between the first transistor T1 and second transistor T2.

Thus, the second activating device 52 is configured to switch from the activated state to the deactivated state when the absolute value of the voltage determined by the second auxiliary voltage detector 62 is less than the second voltage Vₙₒₘ and when the current determined by the second current detector 72 is zero. In other words, the second activating device 52 is able to switch from the activated state to the deactivated state only when the first condition C1 and second condition C2 are both met, the validations of these two conditions, namely the first condition C1 and second condition C2, being transmitted by the second auxiliary voltage detector 62 and by the second current detector 72, respectively. In contrast, the first activating device 51 switches from the activated state to the deactivated state only when the first condition C1 and second condition C2 are both met, the validations of these two conditions, namely the first condition C1 and second condition C2, being transmitted by the first auxiliary voltage detector 61 and by the second current detector 72, respectively.

Therefore, when the first condition C1 and second condition C2 are met, there is an absence of overvoltage, the electrical generation line L1-L2 and the line 10 are in a nominal operating state, and the second regulator 42 is inactive.

In contrast, the only condition that must be met for the second device 52 for activating the second regulator 42 to switch from the deactivated state to the activated state is detection by the second overvoltage detector 22 of a voltage of absolute value greater than the first threshold voltage V_{high} and therefore of an overvoltage level OvH. In other words, the second regulator 42 is able to switch from the deactivated state to the activated state only if the voltage measured by the second overvoltage detector 22 is less than the third threshold voltage V′_{high}, in the case where

$$‖ {V}_{high}^{′} ‖ = ‖ {V}_{high} ‖ .$$

Therefore, an overvoltage is present, the electrical generation line L1-L2 and the line 10 are in a malfunctioning state, and the second regulator 42 is active.

Furthermore, the protecting device 1 may also comprise a device 8 for opening the protecting device 1. This opening device 8 plays a role of protecting the generation line L1-L2 from a potential overvoltage generated by the protecting device 1 following malfunction of the first current source S1 or second current source S2. The opening device 8 is thus configured to open the line 10 so as to no longer allow current to be transmitted in the line 10.

By way of indicative example, the opening device 8 may be a controlled switch, a circuit breaker or, according to one preferred aspect, a fuse.

The opening device 8 may be positioned anywhere in the line 10, i.e. between the first terminal L1 and the first source S1, or between the first source S1 and the second source S2 or even between the second source S2 and the second terminal L2.

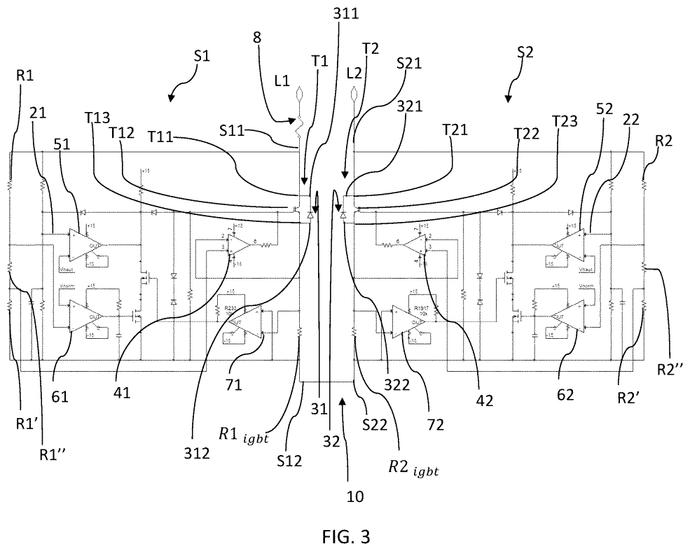

FIG. 3 thus shows a structural view of the protecting device 1. Thus, it may be envisioned for the first overvoltage detector 21, the first auxiliary voltage detector 61, the first current detector 71 and the first current regulator 41 to be operational amplifiers. Furthermore, identically, the second overvoltage detector 22, the second auxiliary voltage detector 62, the second current detector 72 and the second current regulator 42 may also be operational amplifiers. As a variant, a set of transistors may be envisioned.

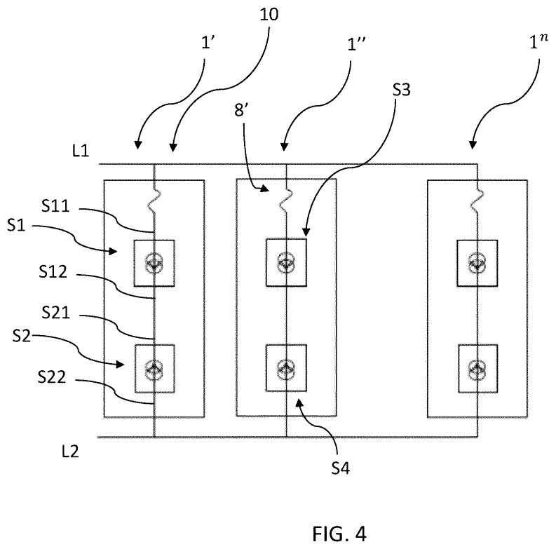

Thus, the assembly consisting of the opening device 8, first current source S1 and second current source S2, forming the line 10 in particular, thus form a first protecting unit 1′. Thus, it may be envisioned for the protecting device 1 to comprise a plurality of protecting units, as shown in FIG. 4, with a second additional protecting unit 1″ and an n^{th} additional protecting unit 1″.

Each additional protecting unit thus comprises a structure equivalent to the first protecting unit 1′, i.e. each additional protecting unit comprises a first additional current source S3 identical to the first current source S1, a second additional current source S4 identical to the second current source S2 and an additional opening device 8′. Furthermore, as in the first protecting unit 1′, the first additional current source S3 is opposed to the second additional current source S4.

Each additional protecting unit 1″ to 1ⁿ is shunted with the first protecting unit 1′ and the electrical generation line L1-L2 so as to regulate the current effectively and limit any detected overvoltage.

Specifically, the overvoltage generated across the first terminal L1 and second terminal L2 has a defined energy. Use of a plurality of protecting units, comprising the first protecting unit 1′ as shown in FIGS. 1 to 3, and one or more additional protecting units 1″ to 1ⁿ, has the advantage of distributing the absorption of the energy generated by the overvoltage between a plurality of lines without adding any component dedicated to such absorption. Thus, by way of indicative example, for an overvoltage generating an energy equivalent in magnitude to one hundred watts, it is possible to envision use of a single protecting unit 1′. Furthermore, for an overvoltage generating, for example, an energy equivalent in magnitude to about two hundred watts, it may then be envisioned to add an additional protecting unit 1″. The protecting device 1 then comprises two protecting units 1′ and 1″ placed in parallel with each other and also in parallel with the electrical generation line L1-L2.

Furthermore, use of a plurality of additional protecting units also has the advantage of allowing the protecting device 1 to operate even should one of the additional protecting units not be operating correctly and it be necessary to open the line of the defective additional protecting unit via the additional opening device 8′ of the defective additional protecting unit.

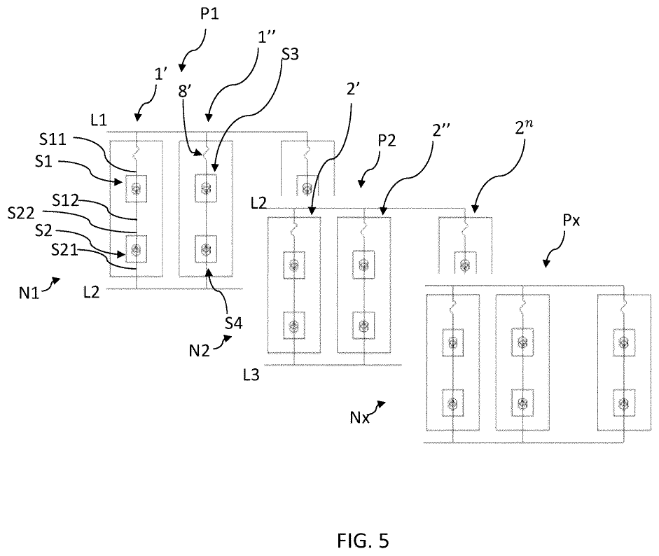

Furthermore, in the case of an electrical machine having a plurality of phases, as shown in FIG. 5, it may be envisioned for each phase to comprise an assembly of one or more protecting units in order to protect each phase of the electrical machine against a potential overvoltage. Thus, a first phase N1 formed between the first terminal L1 and second terminal L2 may comprise a first protecting assembly P1 formed by the first protecting unit 1′ and possibly by one or more additional protecting units 1″ to 1ⁿ. Furthermore, for a second phase N2 of the electrical machine formed between the second terminal L2 and a third terminal L3, it may also be envisioned to incorporate a second protecting assembly P2 formed by a second main protecting unit 2′ and possibly by one or more additional protecting units 2″ to 2ⁿ. Furthermore, similarly, each phase Nx formed between two terminals may comprise an identical protecting assembly Px.

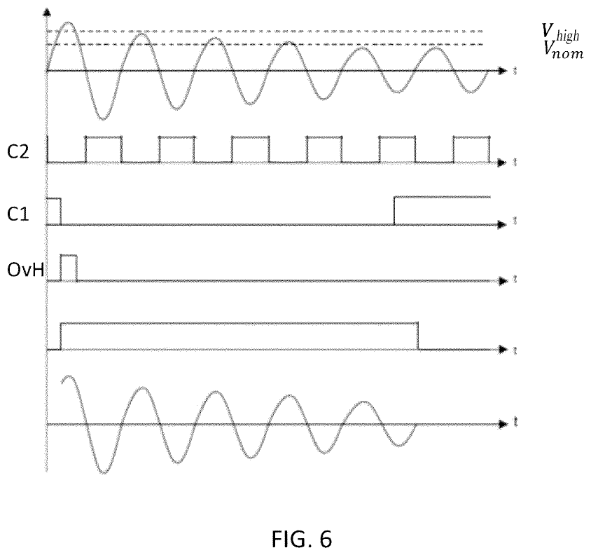

FIG. 6 shows a timing diagram of the variation over time of an overvoltage detected by the protecting device 1.

The first row of this timing diagram shows the voltage measured by the first overvoltage detector 21 or by the second overvoltage detector 22, depending on the direction of the current, and by the first auxiliary voltage detector 61 or by the second auxiliary voltage detector 62, depending on the direction of the current, in the electrical generation line L1-L2 between the first terminal L1 and second terminal L2. This first row of the timing diagram also shows the first threshold voltage V_{high} allowing an overvoltage level OvH to be detected and the second threshold voltage Vₙₒₘ allowing a nominal voltage and the end of the measured overvoltage to be detected.

Thus, as shown in the first row of the timing diagram, an overvoltage is detected with a voltage measurement, by the first overvoltage detector 21 or by the second overvoltage detector 22, depending on the direction of the current, greater than the first threshold voltage V_{high}.

The second row of the timing diagram of FIG. 6 is a binary representation of the cancellation of the current measured by the first current detector 71 or by the second current detector 72 in the protecting device 1, and more particularly in the line 10. More precisely, this signal is a square-wave representation each edge of which represents a cancellation of the current in the line 10, thus making it possible to meet the second condition C2 allowing the first device 51 for activating the first regulator 41 or the second device 52 for activating the second regulator 42 to be switched between the activated state and the deactivated state. Thus, the second condition C2 is met at each edge of the square wave.

The third row of the timing diagram is also a binary representation of detection by the first auxiliary voltage detector 61 or second auxiliary voltage detector 62, depending on the direction of the current, of a voltage lower than the second threshold voltage Vₙₒₘ. More precisely, the binary signal is in a high position when the voltage measured by the first auxiliary voltage detector 61 or second auxiliary voltage detector 62 is less than the second threshold voltage Vₙₒₘ and in a low position when the measured voltage is greater than the second threshold voltage Vₙₒₘ. In other words, the third row of the timing diagram is a binary representation of whether or not the first condition C1 allowing the first device 51 for activating the first regulator 41 or the second device 52 for activating the second regulator 42 to be switched between the activated state and the deactivated state has been met. Therefore, the first condition C1 is met when the signal is in its high position.

Thus, the second row and third row of the timing diagram of FIG. 6 are graphical representations of the cumulative conditions, namely the first condition C1 and second condition C2, allowing the first device 51 for activating the first regulator 41 or the second device 52 for activating the second regulator 42 to be switched between the activated state and the deactivated state. Thus, the second condition C2 is met at each edge of the square wave. Therefore, this switch between the activated state and deactivated state occurs when, simultaneously, an edge is detected in the square-wave signal of the second row and the signal of the third row is in its high position.

The fourth row of the timing diagram of FIG. 6 represents detection of an overvoltage level OvH by the first overvoltage detector 21 or by the second overvoltage detector 22, depending on the direction of the current in the electrical generation line L1-L2. This detection has been indicated by a binary representation in which a high position represents a detected overvoltage and a low position represents absence of overvoltage detection. Thus, the first device 51 for activating the first regulator 41 or the second device 52 for activating the second regulator 42 switches from the deactivated state to the activated state when the overvoltage level is detected, i.e. when this signal toggles to the high position.

The fifth row of the timing diagram of FIG. 6 then shows the time for which the first device 51 for activating the first regulator 41 or the second device 52 for activating the second regulator 42 remains in the activated state or in the deactivated state. More precisely, the binary representation indicates that when the signal is in a high position, then the first device 51 for activating the first regulator 41 or the second device 52 for activating the second regulator 42 is in the activated state following detection of an overvoltage, whereas when the signal is in a low position, then the first device 51 for activating the first regulator 41 or the second device 52 for activating the second regulator 42 is in the deactivated state following simultaneous detection of the first condition C1 and of the second condition C2.

Lastly, the fifth row of the timing diagram of FIG. 6 shows the value of the voltage across the first terminal L1 and second terminal L2 following an overvoltage, highlighting limitation of the detected overvoltage after a short time by means of the protecting device 1.

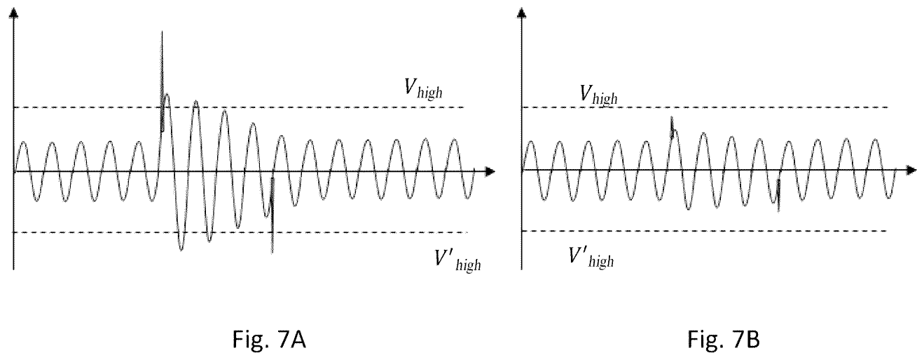

FIGS. 7A and 7B thus show waveforms associated with the voltage measured in an electrical generation line L1-L2 passing an alternating current. More precisely, FIG. 7A shows a situation in which the electrical generation line L1-L2 operates without protection by the protecting device, whereas FIG. 7B shows a situation in which the electrical generation line L1-L2 is protected, in the event of an overvoltage, by the protecting device 1.

Thus, the protecting device 1 makes it possible to limit any detected overvoltage above the thresholds V_{high} and V′_{high} so as not to impact the electrical components present in the electrical generation line L1-L2.

The objective of the proposed protecting device 1 is therefore, via a single means, to prevent fast and slow overvoltages without distortion and without reducing the power available to the electrical network. The modularity of this means makes it possible to apply and adapt this protection function to the energies to be absorbed, irrespectively of whether they are relatively high or relatively low.

The protecting device 1 is characterized by:
its quick response time, which is less than one microsecond, in the case of the type of transient overvoltages referred to as “fast”,
its low distortion, which is less than 2%, in the case of the type of overvoltages referred to as “slow”, i.e. having the frequency of the electrical generation, i.e. a frequency range of about 50/60 Hz, 400/800 Hz for example,
its ability to independently clip positive and negative overvoltages,
its lack of impact on the power available to the generation line, i.e. protection is disconnected when the overvoltage is in the desired range,
the fact that it does not itself generate an overvoltage on its disconnection,
the fact that it alone is able to protect against both fast overvoltages and slow overvoltages,
the fact that it allows redundancy to be created to ensure the availability of the protection function,
the fact that it is modular allowing the protecting device 1 to be adapted to the energy to be absorbed depending on the overvoltage and on the relatively short or long time in the generation line,
the fact that it comprises a safety device, i.e. an element that opens if the protection function is short-circuited,
the fact that it is able to achieve automatic regulation so as to guarantee the availability of the protection function.

1. An electrical power generator configured to deliver electrical power to a load (CH) through an alternating-current generation line (L1-L2), the electrical power generator comprising a device for protecting against fast overvoltages and slow overvoltages, placed in parallel with the alternating-current generation line (L1-L2), the protecting device comprising:
a first current source (S1) comprising an input (S11) and an output (S12), the input (S11) of the first current source (S1) being connected to a first terminal (L1) of the generation line,
a second current source (S2) comprising an input (S21) and an output (S22), the input (S21) of the second current source (S2) being connected to a second terminal (L2) of the generation line, the output (S22) of the second current source (S2) being connected to the output (S12) of the first current source (S1).

2. The electrical power generator as claimed in claim 1, wherein the first current source (S1) and/or second current source (S2) are/is configured to generate a current proportional to a voltage measurable at the first current source (S1) or second current source (S2).

3. The electrical power generator as claimed in claim 1, wherein the device for protecting against overvoltages comprises an overvoltage detector configured to detect an overvoltage level between the first terminal (L1) and second terminal (L2) of the generation line (L1-L2), the overvoltage level being a voltage across the first terminal (L1) and second terminal (L2) of the generation line (L1-L2) greater than a first predefined threshold voltage.

4. The electrical power generator as claimed in claim 3, wherein the first current source (S1) comprises:
a first transistor (T1), the first transistor (T1) comprising:
a first terminal (T11) connected to the first terminal (L1) of the generation line (L1-L2),
a second terminal (T12) connected to the first terminal (L1) of the generation line (L1-L2),
a third terminal (T13) connected to the second current source (S2),
a first diode comprising a cathode connected to the first terminal (T11) of the first transistor (T1) and an anode connected to the third terminal (T13) of the first transistor (T1),
a first resistor (R1) placed between the first terminal (L1) of the generation line (L1-L2) and the second terminal (T12) of the first transistor (T1) and connected to the overvoltage detector,
a first current regulator connected to the overvoltage detector, placed between the first resistor (R1) and the second terminal (T12) of the first transistor (T1) and configured to limit the current flowing through the first transistor (T1) to a predefined current.

5. The electrical power generator as claimed in claim 4, wherein the first current source (S1) comprises a first device for activating the first regulator, which device is connected to the overvoltage detector and configured to switch from a deactivated state, in which the first regulator is inactive, to an activated state, in which the first regulator is active, when the overvoltage detector detects the overvoltage level, the first activating device comprising:
a first auxiliary voltage detector configured to determine a voltage across the first terminal (L1) and second terminal (L2) of the generation line (L1-L2),
a first current detector, which is placed between the third terminal (T13) of the first transistor (T1) and the second current source (S2) and configured to determine a current at the third terminal (T13) of the first transistor (T1),
the first activating device being configured to switch from the activated state to the deactivated state when the voltage determined by the first auxiliary voltage detector is less than a second predefined voltage and when the current determined by the first current detector is zero.

6. The electrical power generator as claimed in claim 3, wherein the second current source (S2) comprises:
a second transistor (T2), the second transistor (T2) comprising:
a first terminal (T21) connected to the second terminal (L2) of the generation line (L1-L2),
a second terminal (T22) connected to the second terminal (L2) of the generation line (L1-L2),
a third terminal (T23) connected to the first current source (S1),
a second diode comprising a cathode connected to the first terminal (T21) of the second transistor (T2) and an anode connected to the third terminal (T23) of the second transistor (T2),
a second resistor (R2) placed between the second terminal (L2) of the generation line (L1-L2) and the second terminal (T22) of the second transistor (T2) and connected to the overvoltage detector (21-22),
a second current regulator connected to the overvoltage detector, placed between the second resistor (R2) and the second terminal (T22) of the second transistor (T2) and configured to limit the current flowing through the second transistor (T2) to a predefined current.

7. The electrical power generator as claimed in claim 6, wherein the second current source (S2) comprises a second device for activating the second regulator, which device is connected to the overvoltage detector and configured to switch from a deactivated state, in which the second regulator is inactive, to an activated state, in which the second regulator is active, when the overvoltage detector detects the overvoltage level, the second activating device comprising:
a second auxiliary voltage detector configured to determine a voltage across the first terminal (L1) and second terminal (L2) of the generation line (L1-L2),
a second current detector, which is placed between the third terminal (T32) of the second transistor (T2) and the first current source (S1) and configured to determine a current at the third terminal (T32) of the second transistor (T2),
the second activating device being configured to switch from the activated state to the deactivated state when the voltage determined by the second auxiliary voltage detector is less than a third predefined voltage and when the current determined by the second current detector is zero.

8. The electrical power generator as claimed in claim 4, wherein the first transistor (T1) is a bipolar transistor.

9. The electrical power generator as claimed in claim 6, wherein the second transistor (T2) is a bipolar transistor.

10. The electrical power generator as claimed in claim 1, wherein the protecting device comprises a device for opening the protecting device.

11. The electrical power generator as claimed in claim 1, wherein the protecting device comprises a first protecting unit, the first protecting unit comprising the first current source (S1) and the second current source (S2), the protecting device comprising at least one additional protecting unit comprising a first additional current source (S3) identical to the first current source (S1) and a second additional current source (S4) identical to the second current source (S2), the at least one additional protecting unit shunting the first protecting unit.
